(19) United States
(12) Patent Application Publication
(10) Pub. No.: US 2015/0380624 A1
(43) Pub. Date: Dec. 31, 2015

(54) METHOD OF MANUFACTURING THERMOELECTRIC CONVERSION MATERIAL

(71) Applicant: Panasonic Corporation, Osaka (JP)

(72) Inventors: Hiromasa TAMAKI, Osaka (JP); Tsutomu KANNO, Kyoto (JP); Akihiro SAKAI, Nara (JP); Kohei TAKAHASHI, Osaka (JP); Hideo KUSADA, Osaka (JP); Yuka YAMADA, Nara (JP)

(21) Appl. No.: 14/847,362

(22) Filed: Sep. 8, 2015

Related U.S. Application Data
(63) Continuation of application No. PCT/JP2014/001883, filed on Mar. 31, 2014.

(30) Foreign Application Priority Data
Apr. 10, 2013 (JP) 2013-082363

(51) Int. Cl. H01L 35/20; C22C 1/04; C22C 30/04; C22C 30/00; C22C 30/02; C22C 1/02; C22C 12/00

(52) U.S. Cl. CPC H01L 35/20; C22C 1/02; C22C 1/04; C22C 12/00; C22C 30/00; C22C 30/02; C22C 30/04

(57) ABSTRACT

A method of manufacturing a thermoelectric conversion material expressed by a chemical formula X₃T₃Z₄ (X comprises one or more elements selected from Zr, Hf, Y, La, Nb, and Ta, while including at least Zr or Hf; T comprises one or more elements selected from Ni, Co, Cu, Rh, Pd, Ir, and Pt, while including at least Ni; Z comprises one or more elements selected from Sb, Ge, and Sn, while including at least Sb), the method comprising: preparing materials containing elements, which are the X including selected elements, the T including selected elements, and the Z including selected elements; forming an alloy A by melting the materials containing the all selected elements except for Sb; and forming an alloy B by melting the alloy A and the material containing Sb.

### CROSS-REFERENCE TO RELATED APPLICATIONS

This is a continuation application of International Application No. PCT/JP2014/001883, with an international filing date of Mar. 31, 2014, which claims priority of Japanese Patent Application No. 2013-82363 filed on Apr. 10, 2013, the contents of which is incorporated herein by reference.

### BACKGROUND OF THE INVENTION

(1) Field of the Invention

This disclosure relates to a method of manufacturing a thermoelectric conversion material utilized for thermoelectric power generation and thermoelectric cooling.

(2) Description of Related Art

The thermoelectric power generation is a technology of converting thermal energy directly into electric energy by utilizing the Seebeck effect i.e., thermoelectromotive force generated between both ends of a substance by a temperature difference made between the both ends of the substance in proportion to the temperature difference. This technology is practically used as a power source for a remote place, a power source for space use, a power source for military use, etc. in some cases.

The thermoelectric cooling is a technology using the Peltier effect, i.e., a phenomenon of transferring heat through electrons carried by an electric current. Specifically, the thermoelectric cooling is a technology of absorbing heat of a joint part by utilizing a fact that when an electric current is applied to two substances different in polarity of electric conduction carriers connected thermally in parallel and electrically in series, the difference in polarity of the electric conduction carriers (carriers) is reflected on a difference in direction of a heat flow. For example, the two substances different in polarity of electric conduction carriers used in this case are a p-type semiconductor having the electric conduction carriers (carrier) that are holes and an n-type semiconductor having the electric conduction carriers (carriers) that are electrons. Such an element configuration is of a so-called π type and is a most common configuration.

The energy conversion efficiency between heat and electricity in thermoelectric power generation and thermoelectric cooling is determined by a figure of merit ZT of material used. The figure of merit ZT is expressed by using a Seebeck coefficient S, an electric resistivity p, and a thermal conductivity κ of the material and an absolute temperature T of evaluation environment as ZT=S²T/ρκ. The energy conversion efficiency becomes higher when the figure of merit ZT is higher. Therefore, a semiconductor with a high absolute value of Seebeck coefficient S, a low electric resistivity ρ, and a low thermal conductivity κ is a necessary condition for achieving the high figure of merit ZT.

### Nonpatent Literature 1

J. R. Salvador, X. Shi, J. Yang and H. Wang, “Synthesis and transport properties of M₃Ni₃Sb₄ (M=Zr and Hf): An intermetallic semiconductor”, Physical Review B 77, 235217, Jun. 27, 2008

### SUMMARY

A sample formed by a conventional manufacturing method has a low Seebeck coefficient S and cannot form uniform crystals. Therefore, a highly reliable manufacturing method must be established for extracting the thermoelectric conversion characteristics specific to a thermoelectric conversion material X₃Ni₃Sb₄ (X=Zr, Hf).

One non-limiting and exemplary embodiment provides a highly reliable method of manufacturing the thermoelectric conversion material X₃Ni₃Sb₄ (X=Zr, Hf).

In one general aspect, the techniques disclosed here feature: a method of manufacturing a thermoelectric conversion material expressed by a chemical formula X₃T₃Z₄ (X is composed of one or more elements selected from Zr, Hf, Y, La, Nb, and Ta, while including at least Zr or Hf; T is composed of one or more elements selected from Ni, Co, Cu, Rh, Pd, Ir, and Pt, while including at least Ni; Z is composed of one or more elements selected from Sb, Ge, and Sn, while including at least Sb), the method includes:

preparing materials containing elements, which are one or more elements selected from Zr, Hf, Y, La, Nb, and Ta, while including at least Zr or Hf, one or more elements selected from Ni, Co, Cu, Rh, Pd, Ir, and Pt, while including at least Ni, and one or more elements selected from Sb, Ge, and Sn, while including at least Sb;

forming an alloy A by melting the materials containing desired elements selected from Zr, Hf, Y, La, Nb, Ta, Ni, Co, Cu, Rh, Pd, Ir, Pt, Ge, and Sn; and

forming an alloy B by melting the alloy A and the material containing Sb.

The method of manufacturing a thermoelectric conversion material according to this disclosure can provide an intermetallic compound X₃T₃Z₄ (X is composed of one or more elements selected from Zr, Hf, Y, La, Nb, and Ta, while including at least Zr or Hf; T is composed of one or more elements selected from Ni, Co, Cu, Rh, Pd, Ir, and Pt, while including at least Ni; Z is composed of one or more elements selected from Sb, Ge, and Sn, while including at least Sb) having a high Seebeck coefficient.

The method of manufacturing a thermoelectric conversion material according to this disclosure enables production of a thermoelectric conversion material exhibiting a high Seebeck coefficient S in the thermoelectric conversion material Zr₃₋ₓHfₓNi₃Sb₄ and an element-substituted material system of Zr₃₋ₓHfₓNi₃Sb₄.

Additional benefits and advantages of the disclosed embodiments will be apparent from the specification and figures. The benefits and/or advantages may be individually provided by the various embodiments and features of the specification and drawings disclosure, and need not all be provided in order to obtain one or more of the same.

### BRIEF DESCRIPTION OF DRAWINGS

The present disclosure will become readily understood from the following description of non-limiting and exemplary embodiments thereof made with reference to the accompanying drawings, in which like parts are designated by like reference numeral and in which:

FIG. 1 is a schematic of a crystal structure of a thermoelectric conversion material X₃T₃Z₄ of this disclosure;

FIG. 2 is a flowchart of processes of a manufacturing method of this disclosure;

FIG. 3 is a flowchart of processes of a manufacturing method of a comparison example 1; and

FIG. 4 is a flowchart of processes of a manufacturing method of a comparison example 2.

### DETAILED DESCRIPTION

According to a first aspect, a method of manufacturing a thermoelectric conversion material expressed by a chemical formula X₃T₃Z₄ (X is composed of one or more elements selected from Zr, Hf, Y, La, Nb, and Ta, while including at least Zr or Hf; T is composed of one or more elements selected from Ni, Co, Cu, Rh, Pd, Ir, and Pt, while including at least Ni; Z is composed of one or more elements selected from Sb, Ge, and Sn, while including at least Sb), the method includes:

preparing materials containing elements, which are one or more elements selected from Zr, Hf, Y, La, Nb, and Ta, while including at least Zr or Hf, one or more elements selected from Ni, Co, Cu, Rh, Pd, Ir, and Pt, while including at least Ni, and one or more elements selected from Sb, Ge, and Sn, while including at least Sb;

forming an alloy A by melting the materials containing desired elements selected from Zr, Hf, Y, La, Nb, Ta, Ni, Co, Cu, Rh, Pd, Ir, Pt, Ge, and Sn; and

forming an alloy B by melting the alloy A and the material containing Sb.

Further, as a method of manufacturing a thermoelectric conversion material of a second aspect, in the first aspect, the step of forming the alloy A may be performed by any one of an arc melting method, an electromagnetic induction heating method, and a heating method using a resistance heating element.

Further, as a method of manufacturing a thermoelectric conversion material of a third aspect, in the first aspect, in the step of forming the alloy A, the alloy A may be formed by melting the materials containing the elements except the material containing Sb at 2000° C. or higher.

Further, as a method of manufacturing a thermoelectric conversion material of a fourth aspect, in the first aspect, in the step of forming the alloy B, the alloy B may be formed by melting the alloy A and the material containing Sb at 1500° C. or lower.

Further, as a method of manufacturing a thermoelectric conversion material of a fifth aspect, in the first aspect, the method may further include a step of forming a sintered body having a density higher than the alloy B by using the alloy B after the step of forming the alloy B.

Further, as a method of manufacturing a thermoelectric conversion material of a sixth aspect, in the fifth aspect, the step of forming a sintered body having a density higher than the alloy B by using the alloy B may be performed by either a hot press method or a spark plasma sintering method (SPS method).

Further, as a method of manufacturing a thermoelectric conversion material of a seventh aspect, in the first aspect, X may be composed of one or more elements selected from Zr and Hf; T may be composed of one or more elements selected from Ni, Co, Cu, Pd, and Pt, while including at least Ni; Z may be composed of one or more elements selected from Sb and Sn, while including at least Sb.

The method of manufacturing a thermoelectric conversion material according to an embodiment of this disclosure will now be described with reference to the drawings.

### First Embodiment

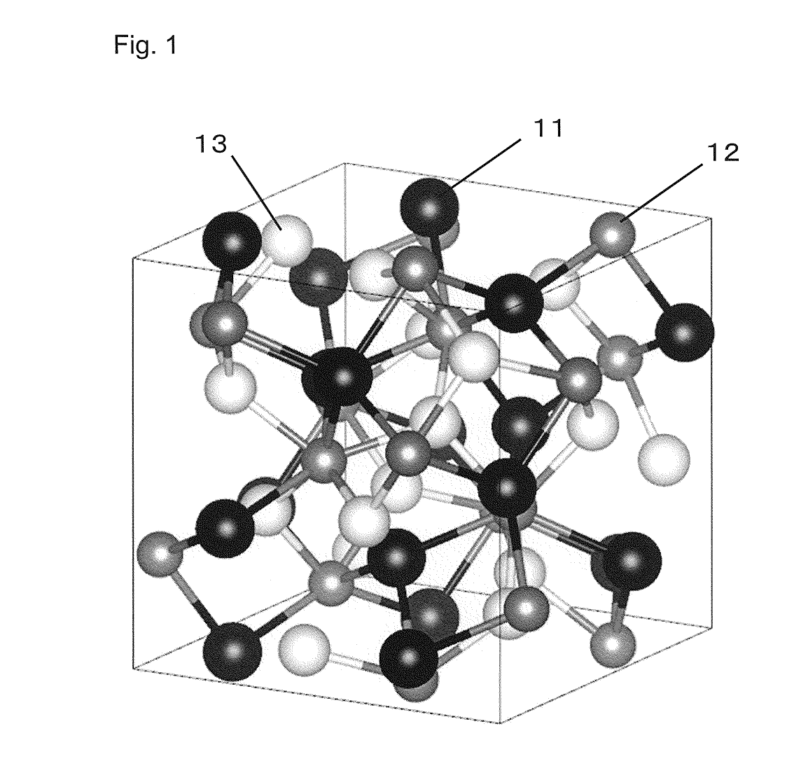

Description will be made of a method of manufacturing the thermoelectric conversion material X₃T₃Z₄ (X is composed of one or more elements selected from Zr, Hf, Y, La, Nb, and Ta, while including at least Zr or Hf; T is composed of one or more elements selected from Ni, Co, Cu, Rh, Pd, Ir, and Pt, while including at least Ni; Z is composed of one or more elements selected from Sb, Ge, and Sn, while including at least Sb) according to a first embodiment of this disclosure. The compound X₃T₃Z₄ is a thermoelectric conversion material and has symmetry of a cubic crystal belonging to a space group I-43d. FIG. 1 is a schematic of a crystal structure of the thermoelectric conversion material X₃T₃Z₄. As depicted in FIG. 1, the thermoelectric conversion material X₃T₃Z₄ has the crystal structure in which atoms are arranged at a ratio of X:T:Z=3:3:4 in a unit cell.

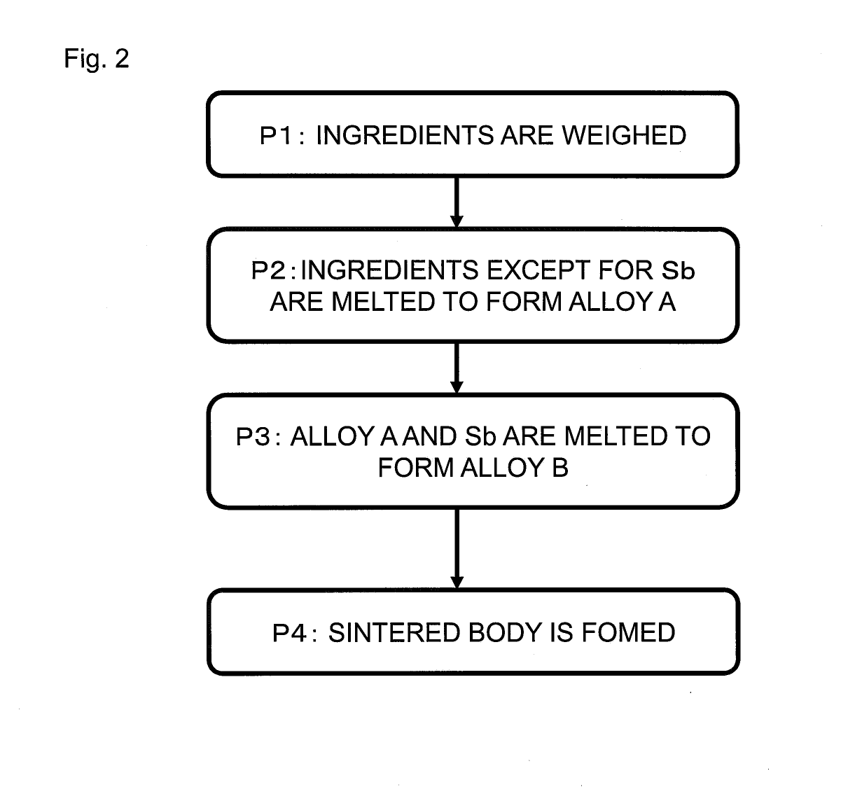

FIG. 2 is a flowchart of processes of the method of manufacturing a thermoelectric conversion material according to the first embodiment. The method of manufacturing is as depicted in FIG. 2 and the detailed execution procedure of manufacturing will hereinafter be described.

(1) First, ingredients containing necessary elements selected from Zr, Hf, Y, La, Nb, Ta, Ni, Co, Cu, Rh, Pd, Ir, Pt, Sn, Ge, and Sb are weighed to a stoichiometric ratio of (Zr+Hf+Y+La+Nb+Ta):(Ni+Co+Cu+Rh+Pd+Ir+Pt):(Sb+Ge+Sn)=3:3:4 (process P1).

(2) Among the weighed ingredients, the ingredients containing desired elements selected from Zr, Hf, Y, La, Nb, Ta, Ni, Co, Cu, Rh, Pd, Ir, Pt, Ge, and Sn are alloyed to acquire an alloy A (first alloy) (process P2). The alloy A may be formed by melting ingredients containing a substance other than Zr, Hf, Y, La, Nb, Ta, Ni, Co, Cu, Rh, Pd, Ir, Pt, Ge, and Sn at an impurity level. The “impurity level” in this case refers to less than 1% relative to the weight ratio of the ingredients containing desired elements selected from Zr, Hf, Y, La, Nb, Ta, Ni, Co, Cu, Rh, Pd, Ir, Pt, Ge, and Sn. In the process P2, all the weighed ingredients except Sb may be alloyed to acquire the alloy A. The method of alloying is not particularly limited and the specific methods include, for example, an arc melting method, an electromagnetic induction heating method, and a heating method using a resistance heating element.

(3) The acquired alloy A and Sb are alloyed to acquire an alloy B (second alloy) (process P3). As is the case with the process P2, the method of alloying in the process P3 is not particularly limited.

If a sintered body with a density higher than the alloy B is formed by using the alloy B acquired in the process P3, a process P4 of sintering may further be provided. The method of sintering may be a hot press method, a spark plasma sintering method (SPS method), etc. If the SPS method is used, after the alloy acquired in the process P3 is ground on a mortar etc., a pulsed current is applied while the alloy is pressurized to 50 MPa, so as to increase temperature to 800 to 900° C., and the temperature is then retained for 5 minutes, thereby acquiring a sintered body of the compound X₃T₃Z₄.

### Example 1

A sintered body was formed by the manufacturing method described in the first embodiment from the compound X₃T₃Z₄ (X is composed of one or more elements selected from Zr, Hf, Y, La, Nb, and Ta, while including at least Zr or Hf; T is composed of one or more elements selected from Ni, Co, Cu, Rh, Pd, Ir, and Pt, while including at least Ni; Z is composed of one or more elements selected from Sb, Ge, and Sn, while including at least Sb).

A specific manufacturing method will first be described.

(a) Zr, Hf, Y, La, Nb, Ta, Ni, Co, Cu, Rh, Pd, Ir, Pt, Sn, Ge, and Sb used as ingredients were weighed to a stoichiometric ratio of Zr+Hf+Y+La+Nb+Ta:Ni+Co+Cu+Rh+Pd+Ir+Pt:Ge+Sn+Sb=3:3:4 (process P1). A composition ratio estimated from the weighed ingredients is referred to as preparation composition.

(b) Among the weighed ingredients, the ingredients except Sb (materials containing desired elements selected from Zr, Hf, Y, La, Nb, Ta, Ni, Co, Cu, Rh, Pd, Ir, Pt, Ge, and Sn) were alloyed by the arc melting method (process P2).

The arc melting method was performed by the following procedure.

(i) First, the ingredients Zr, Hf, Y, La, Nb, Ta, Ni, Co, Cu, Rh, Pd, Ir, Pt, Ge, and Sn were placed on a copper hearth liner and the atmosphere is filled with Ar.

(ii) The ingredients on the hearth liner were melted at a high temperature of 2000° C. or higher by applying arc discharge. The copper hearth liner was cooled by cooling water to quench a sample, thereby acquiring the alloy A.

(iii) An operation of reversing the alloy A and performing the arc discharge again was further repeated three times to acquire the more uniform alloy A.

(c) The acquired alloy A and Sb are alloyed by using the arc melting method (process P3). The arc discharge in this case was performed by using discharge of weak power as compared to the process P2 to the extent that the alloy was at 1500° C. or lower.

(d) To form a denser sample, a sintered body was formed by a discharge plasma sintering method. The discharge plasma sintering method is a sintering method using pressurization and pulse energization at the same time.

(i) The alloy B acquired in the process P3 is finely ground by using a mortar and a pestle in a glove box under an Ar atmosphere so as to avoid oxidization.

(ii) The acquired powder was filled in a cylindrical graphite die having an outer diameter of 50 mm and an inner diameter of 10 mm and was pressurized by graphite punches from above and below the cylinder.

(iii) A pulsed current was applied to this die in a vacuum of 1 Pa or less to increase temperature to about 800 to 900° C. at a rate of about 100° C./min.

(iv) After the temperature of 800 to 900° C. was retained for 5 minutes, slow cooling was performed to acquire a sintered body.

The sintered body was cut into a rectangular parallelepiped of about 2 mm*2 mm*8 mm to acquire a sample for evaluating the Seebeck coefficient S.

The Seebeck coefficient of the cut sample at room temperature was evaluated by a four-terminal method to confirm the superiority of the effect of the manufacturing method of this disclosure. The measurement of the Seebeck coefficient S by the four-terminal method was performed by using the measurement device ZEM-3 manufactured by ULVAC-RIKO in the environment of a helium atmosphere at 0.1 atm. While a temperature difference was generated in the sample longitudinal direction by heating one end in the longitudinal direction, probe electrodes were brought into contact with two points interposed between the both ends in the longitudinal direction to detect a potential difference ΔV and a temperature difference ΔT between the probes. The Seebeck coefficient S was obtained from the generated voltage difference ΔV and temperature difference ΔT by a definitional equation S=−ΔV/ΔT.

Lastly, the actual composition of the sintered body acquired by the manufacturing process was analyzed by using the energy dispersive X-ray spectroscopy (EDX). The EDX method is a method of measuring a ratio of an element near a sample surface from energy distribution of characteristic X-rays generated when an electron beam is applied to a sample. Even in a conventional example, composition analysis is performed by using an electron probe microanalyzer (EPMA), which is an equivalent technique. In this measurement, the composition analysis was performed at four different points on a sample surface by the EDX method to obtain the composition from the average of the four points. In this description, the overall composition is represented by adjusting the abundance of Ni atoms to three in accordance with the Nonpatent Literature 1. In a system having substitution for an Ni atom, the overall composition ratio is represented such that the total number of atoms of Ni, Co, Cu, Rh, Pd, Ir, and Pt including a substituted element is set to three. The sum of the amounts of Sb, Ge, and Sn represented in this way less than four is defined as a state of insufficient Sb.

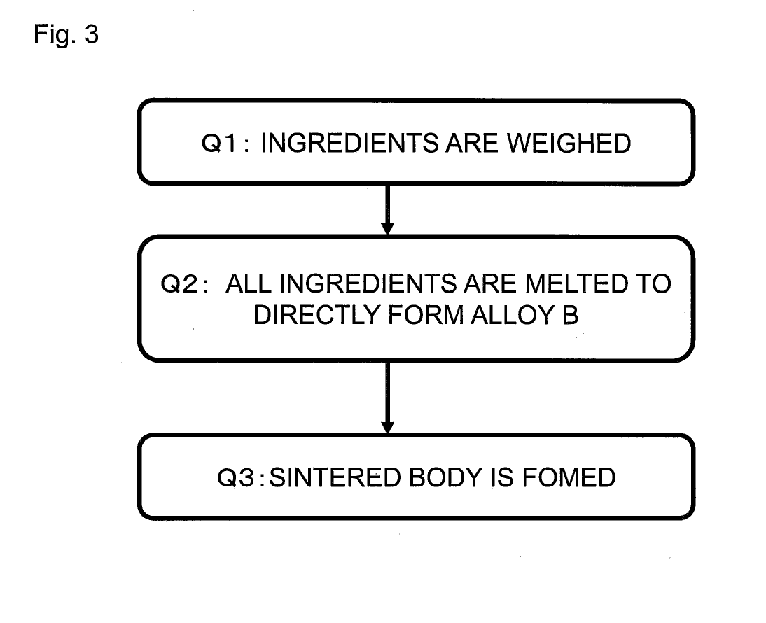

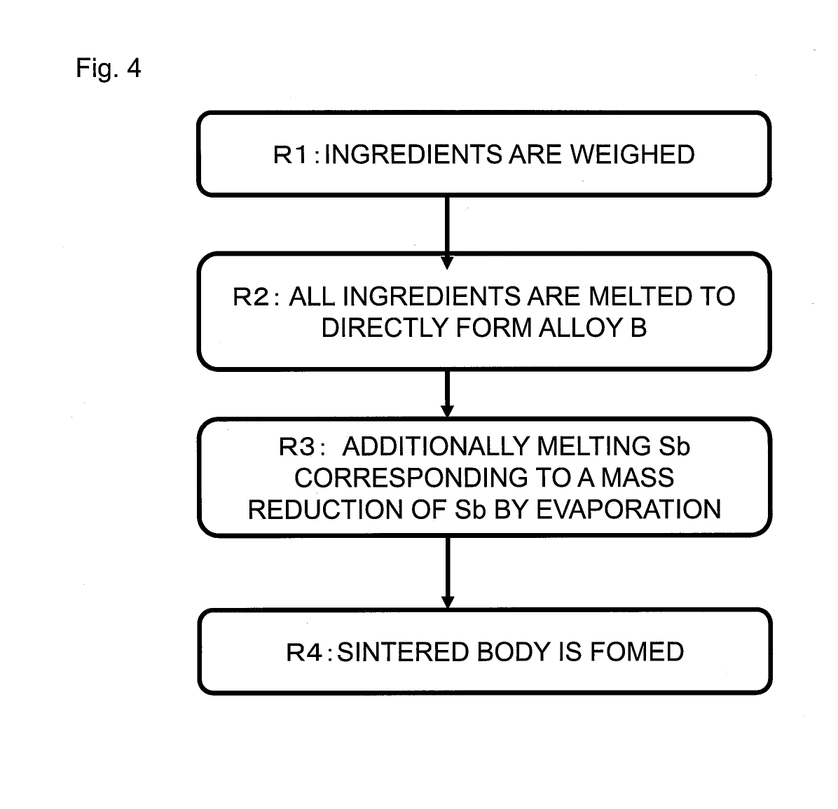

TABLE 1

| | | | | Seebeck |
|---|---|---|---|---|
| | | | | coefficient at |
| | Weighed | | | Room |
| | Preparation | Sintered Body | Manufacturing | Temperature |
| | Composition | Composition | Method | (μV/K) |
| Conventional | Zr₃Ni₃Sb₄ | Zr_{2.8}Ni₃Sb_{3.8} | Nonpatent | 72.4 |
| Example 1 | | | Literature 1 | |
| Conventional | Zr₃Ni₃Sb₄ + Sb | Zr_{2.88}Hf_{0.02}Ni₃Sb_{3.9} | Nonpatent | 66.3 |
| Example 2 | replenishment | | Literature 1 | |
| Conventional | Hf₃Ni₃Sb₄ | Hf_{2.97}Zr_{0.1}Ni₃Sb_{3.72} | Nonpatent | 162 |
| Example 3 | | | Literature 1 | |
| Conventional | Hf₃Ni₃Sb₄ + Sb | Hf_{2.96}Zr_{0.09}Ni₃Sb_{4.07} | Nonpatent | 72.6 |
| Example 4 | added | | Literature 1 | |
| Comparative | Zr₃Ni₃Sb₄ | Zr_{2.96}Ni₃Sb_{3.75} | FIG. 3 | 63.7 |
| Example 1 | | | | |
| Comparative | Zr₃Ni₃Sb₄ + Sb | Zr_{2.97}Ni₃Sb_{4.03} | FIG. 4 | 21.3 |
| Example 2 | replenishment | | | |
| Example 1 | Zr₃Ni₃Sb₄ | Zr_{3.07}Ni₃Sb_{4.14} | FIG. 2 | 232.1 |
| Example 2 | Zr₂HfNi₃Sb₄ | Zr_{1.94}Hf_{1.01}Ni₃Sb_{4.05} | FIG. 2 | 242.7 |
| Example 3 | ZrHf₂Ni₃Sb₄ | Zr_{1.02}Hf_{2.05}Ni₃Sb_{4.09} | FIG. 2 | 229.5 |
| Example 4 | Hf₃Ni₃Sb₄ | Hf_{3.01}Ni₃Sb_{4.13} | FIG. 2 | 237.4 |

Table 1 describes the sintered body compositions and the Seebeck coefficients at room temperature of examples 1 to 4 of sintered bodies of ZrₓHf₃₋ₓNi₃Sb₄ (0≦x≦3) formed under the conditions of X=Zr, Hf and T=Ni and Z=Sb, comparison examples 1, 2 of sintered bodies from a different manufacturing method, and conventional examples 1 to 4 reported in Nonpatent Literature 1 described above. In the conventional examples 2 and 4, the sintered body composition slightly contains Hf although the preparation composition does not contain Hf. In the conventional example 3, the sintered body composition slightly contains Zr although the preparation composition does not contain Zr. It is considered this is because Zr or Hf used as ingredients in Nonpatent Literature 1 contained Hf or Zr as an impurity at about 1%.

The measurement results of the examples 1 to 4 indicate a high Seebeck coefficient exceeding 200 μV/K regardless of a ratio of Zr and Hf.

FIG. 3 is a flowchart of processes of the manufacturing method of the comparison example 1. In the manufacturing method of the comparison example 1, as depicted in FIG. 3, the two steps of the melting processes (P2, P3) in the manufacturing method according to the first embodiment are replaced with a process (Q2) in which all the ingredients including Sb are melted at one step by using the ark melting method. The measurement of composition of a sintered body formed through the process (Q2) by the EDX method revealed that the composition had Sb shifted toward less than four from the stoichiometric ratio of Zr:Ni:Sb=3:3:4 as indicated by Zr_{2.96}Ni₃Sb_{3.75}.

FIG. 4 is a flowchart of processes of the manufacturing method of the comparison example 2. For the comparison example 2, as depicted in FIG. 4, a process (R3) of additionally melting Sb corresponding to a mass reduction by the arc melting method is further introduced so as to compensate the reduction amount of Sb generated in the process (R2). The apparent composition from the EDX method of a sintered body acquired in the comparison example 2 was Zr_{2.97}Ni₃Sb_{4.03} and was close to the preparation composition. The manufacturing method provided with such a step of adding Sb is also performed in Nonpatent Literature 1 described above. When the Seebeck coefficient S at room temperature was measured for the comparison example 1 in which Sb was insufficient and the comparison example 2 in which Sb was not insufficient, the high Seebeck coefficient S as in the example 1 was not acquired. The measurement result of the comparison example 1 means that the insufficiency of the Sb amount decreases the Seebeck coefficient. In the comparison example 2, it is considered that even if the Sb amount is not insufficient, a plurality of metal alloys such as a Zr—Ni alloy and ZrNiSb or a simple substance of Sb is segregated, which appears to prevent the implementation of the high Seebeck coefficient S. From the above, to implement the high Seebeck coefficient in this thermoelectric conversion material, a spatially-uniform crystal state of Zr₃Ni₃Sb₄ must be achieved in a sample.

The conventional examples 1 to 4 indicate the Seebeck coefficients S at room temperature of samples acquired through the process of melting all the ingredients at a time as in the comparison examples 1, 2. The respective Seebeck coefficients at room temperature of the conventional examples are reported for the conventional examples 1, 3 acquired through annealing treatment and a sintering process of an alloy acquired by batch melting and the conventional examples 2, 4 acquired by sintering following the mixing of Sb corresponding to a reduced amount after annealing. A high Seebeck coefficient as in the examples 1 to 4 is not acquired in the conventional examples.

The superiority of the manufacturing method of this disclosure could be confirmed not only in ZrₓHf₃₋ₓNi₃Sb₄ but also in the case of substituting Y, La, Nb, or Ta for a portion of Zr or Hf of ZrₓHf₃₋ₓNi₃Sb₄, in the case of substituting Co, Cu, Rh, Pd, Ir, or Pt for a portion of Ni, or in the case of substituting Ge or Sn for a portion of Sb. In the case of substituting Co, Rh, or Ir for Ni, or in the case of substituting Sn for Sb, a reduction in the number of electrons in crystals provides a hole-doped p-type semiconductor and the Seebeck coefficient S takes a positive value (S>0). In the case of substituting Nb or Ta for Zr or Hf, or in the case of substituting Cu for Ni, an electron-doped n-type semiconductor is provided and the Seebeck coefficient S takes a negative value (S<0). For the element-substituted alloys, the Seebeck coefficient S at room temperature is described below for the samples (examples and comparison examples) formed by using the respective manufacturing methods of FIG. 2 of this disclosure and FIG. 3 of the comparison example.

### Example 5 and Comparative Example 5

When a preparation composition was Zr₃Ni_{2.9}Co_{0.1}Sb₄, a sintered body was manufactured by the manufacturing method according to this disclosure of FIG. 2 (example 5) and a sintered body was manufactured by the conventional manufacturing method of FIG. 3 (comparative example 5). Table 2 is a table describing the preparation compositions, the compositions of the respective sintered bodies, the figures depicting the flowcharts of the manufacturing methods, and the Seebeck coefficients at room temperature. Referring to Table 2, the example 5 employing the manufacturing method of FIG. 2 contained a larger amount of Sb as compared to the comparison example 5 employing the manufacturing method of FIG. 3. It is considered that the sample exhibiting a larger absolute value of the Seebeck coefficient could consequently be acquired.

TABLE 2

| | | | | Seebeck |
|---|---|---|---|---|
| | | | | coefficient at |
| | | | | Room |
| | Preparation | Sintered Body | Manufacturing | Temperature |
| | Composition | Composition | Method | (μV/K) |
| Example 5 | Zr₃Ni_{2.9}Co_{0.1}Sb₄ | Zr_{2.78}Ni_{2.91}Co_{0.09}Sb_{3.78} | FIG. 2 | 170 |
| Comparative | Zr₃Ni_{2.9}Co_{0.1}Sb₄ | Zr_{2.84}Ni_{2.92}Co_{0.08}Sb_{3.59} | FIG. 3 | 91.8 |
| Example 5 | | | | |

### Example 6 and Comparative Example 6

When a preparation composition was Zr₃Ni_{2.7}Co_{0.3}Sb₄, a sintered body was manufactured by the manufacturing method according to this disclosure of FIG. 2 (example 6) and a sintered body was manufactured by the conventional manufacturing method of FIG. 3 (comparative example 6). Table 3 is a table describing the preparation compositions, the compositions of the respective sintered bodies, the figures depicting the flowcharts of the manufacturing methods, and the Seebeck coefficients at room temperature. Referring to Table 3, the example 6 employing the manufacturing method of FIG. 2 contained a larger amount of Sb as compared to the comparative example 6 employing the manufacturing method of FIG. 3. It is considered that the sample exhibiting a larger absolute value of the Seebeck coefficient could consequently be acquired.

TABLE 3

| | | | | Seebeck |
|---|---|---|---|---|
| | | | | coefficient at |
| | | | | Room |
| | Preparation | Sintered Body | Manufacturing | Temperature |
| | Composition | Composition | Method | (μV/K) |
| Example 6 | Zr₃Ni_{2.7}Co_{0.3}Sb₄ | Zr_{3.16}Ni_{2.76}Co_{0.24}Sb_{4.12} | FIG. 2 | 97.5 |
| Comparative | Zr₃Ni_{2.7}Co_{0.3}Sb₄ | Zr_{2.94}Ni_{2.69}Cp_{0.31}Sb_{3.76} | FIG. 3 | 56.1 |
| Example 6 | | | | |

### Example 7 and Comparative Example 7

When a preparation composition was Zr₃Ni_{2.5}Co_{0.5}Sb₄, a sintered body was manufactured by the manufacturing method according to this disclosure of FIG. 2 (example 7) and a sintered body was manufactured by the conventional manufacturing method of FIG. 3 (comparative example 7). Table 4 is a table describing the preparation compositions, the compositions of the respective sintered bodies, the figures depicting the flowcharts of the manufacturing methods, and the Seebeck coefficients at room temperature. Referring to Table 4, the example 7 employing the manufacturing method of FIG. 2 contained a larger amount of Sb as compared to the comparative example 7 employing the manufacturing method of FIG. 3. It is considered that the sample exhibiting a larger absolute value of the Seebeck coefficient could consequently be acquired.

TABLE 4

| | | | | Seebeck |
|---|---|---|---|---|
| | | | | coefficient at |
| | | | | Room |
| | Preparation | Sintered Body | Manufacturing | Temperature |
| | Composition | Composition | Method | (μV/K) |
| Example 7 | Zr₃Ni_{2.5}Co_{0.5}Sb₄ | Zr_{3.2}Ni_{2.52}Co_{0.48}Sb_{4.01} | FIG. 2 | 82 |
| Comparative | Zr₃Ni_{2.5}Co_{0.5}Sb₄ | Zr_{3.01}Ni_{2.51}Co_{0.49}Sb_{3.86} | FIG. 3 | 52.7 |
| Example 7 | | | | |

### Example 8 and Comparative Example 8

When a preparation composition was Zr₃Ni_{2.3}Co_{0.7}Sb₄, a sintered body was manufactured by the manufacturing method according to this disclosure of FIG. 2 (example 8) and a sintered body was manufactured by the conventional manufacturing method of FIG. 3 (comparative example 8). Table 5 is a table describing the preparation compositions, the compositions of the respective sintered bodies, the figures depicting the flowcharts of the manufacturing methods, and the Seebeck coefficients at room temperature. Referring to Table 5, the example 8 employing the manufacturing method of FIG. 2 contained a larger amount of Sb as compared to the comparative example 8 employing the manufacturing method of FIG. 3. It is considered that the sample exhibiting a larger absolute value of the Seebeck coefficient could consequently be acquired.

TABLE 5

| | | | | Seebeck |
|---|---|---|---|---|
| | | | | coefficient at |
| | | | | Room |
| | Preparation | Sintered Body | Manufacturing | Temperature |
| | Composition | Composition | Method | (μV/K) |
| Example 8 | Zr₃Ni_{2.3}Co_{0.7}Sb₄ | Zr_{2.76}Ni_{2.26}Co_{0.74}Sb_{3.92} | FIG. 2 | 63.2 |
| Comparative | Zr₃Ni_{2.3}Co_{0.7}Sb₄ | Zr_{3.24}Ni_{2.32}Co_{0.68}Sb_{3.76} | FIG. 3 | 41.3 |
| Example 8 | | | | |

### Example 9 and Comparative Example 9

When a preparation composition was Zr₃Ni_{2.9}Cu_{0.1}Sb₄, a sintered body was manufactured by the manufacturing method according to this disclosure of FIG. 2 (example 9) and a sintered body was manufactured by the conventional manufacturing method of FIG. 3 (comparative example 9). Table 6 is a table describing the preparation compositions, the compositions of the respective sintered bodies, the figures depicting the flowcharts of the manufacturing methods, and the Seebeck coefficients at room temperature. Referring to Table 6, the example 9 employing the manufacturing method of FIG. 2 contained a larger amount of Sb as compared to the comparative example 9 employing the manufacturing method of FIG. 3. It is considered that the sample exhibiting a larger absolute value of the Seebeck coefficient could consequently be acquired. If Cu is used for a dopant substituted for Ni, an electron-doped n-type semiconductor is provided and the Seebeck coefficient S takes a negative value (S<0).

TABLE 6

| | | | | Seebeck |
|---|---|---|---|---|
| | | | | coefficient at |
| | | | | Room |
| | Preparation | Sintered Body | Manufacturing | Temperature |
| | Composition | Composition | Method | (μV/K) |
| Example 9 | Zr₃Ni_{2.9}Cu_{0.1}Sb₄ | Zr_{3.12}Ni_{2.94}Cu_{0.06}Sb_{4.03} | FIG. 2 | −201 |
| Comparative | Zr₃Ni_{2.9}Cu_{0.1}Sb₄ | Zr_{2.91}Ni_{2.92}Cu_{0.08}Sb_{3.90} | FIG. 3 | 19.1 |
| Example 9 | | | | |

### Example 10 and Comparative Example 10

When a preparation composition was Zr₃Ni_{2.7}Cu_{0.3}Sb₄, a sintered body was manufactured by the manufacturing method according to this disclosure of FIG. 2 (example 10) and a sintered body was manufactured by the conventional manufacturing method of FIG. 3 (comparative example 10). Table 7 is a table describing the preparation compositions, the compositions of the respective sintered bodies, the figures depicting the flowcharts of the manufacturing methods, and the Seebeck coefficients at room temperature. Referring to Table 7, the example 10 employing the manufacturing method of FIG. 2 contained a larger amount of Sb as compared to the comparative example 10 employing the manufacturing method of FIG. 3. It is considered that the sample exhibiting a larger absolute value of the Seebeck coefficient could consequently be acquired.

TABLE 7

| | | | | Seebeck |
|---|---|---|---|---|
| | | | | coefficient at |
| | | | | Room |
| | Preparation | Sintered Body | Manufacturing | Temperature |
| | Composition | Composition | Method | (μV/K) |
| Example 10 | Zr₃Ni_{2.7}Cu_{0.3}Sb₄ | Zr_{3.17}Ni_{2.64}Cu_{0.36}Sb_{3.94} | FIG. 2 | −126 |
| Comparative | Zr₃Ni_{2.7}Cu_{0.3}Sb₄ | Zr_{3.05}Ni_{2.67}Cu_{0.33}Sb_{3.74} | FIG. 3 | −44.2 |
| Example 10 | | | | |

### Example 11 and Comparative Example 11

When a preparation composition was Zr₃Ni_{2.5}Cu_{0.5}Sb₄, a sintered body was manufactured by the manufacturing method according to this disclosure of FIG. 2 (example 11) and a sintered body was manufactured by the conventional manufacturing method of FIG. 3 (comparative example 11). Table 8 is a table describing the preparation compositions, the compositions of the respective sintered bodies, the figures depicting the flowcharts of the manufacturing methods, and the Seebeck coefficients at room temperature. Referring to Table 8, the example 11 employing the manufacturing method of FIG. 2 contained a larger amount of Sb as compared to the comparative example 11 employing the manufacturing method of FIG. 3. It is considered that the sample exhibiting a larger absolute value of the Seebeck coefficient could consequently be acquired.

TABLE 8

| | | | | Seebeck |
|---|---|---|---|---|
| | | | | coef- |
| | | | | ficient |
| | | | | at Room |
| | | | Manu- | Temper- |
| | Preparation | Sintered Body | facturing | ature |
| | Composition | Composition | Method | (μV/K) |
| Ex- | Zr₃Ni_{2.5}Cu_{0.5}Sb₄ | Zr_{2.98}Ni_{2.51}Cu_{0.49}Sb_{4.19} | FIG. 2 | −91.3 |
| ample | | | | |
| 11 | | | | |
| Com- | Zr₃Ni_{2.5}Cu_{0.5}Sb₄ | Zr_{3.07}Ni_{2.43}Cu_{0.57}Sb_{3.94} | FIG. 3 | −36.5 |
| parative | | | | |
| Ex- | | | | |
| ample | | | | |
| 11 | | | | |

### Example 12 and Comparative Example 12

When a preparation composition was Zr₃Ni₃Sb_{3.9}Sn_{0.1}, a sintered body was manufactured by the manufacturing method according to this disclosure of FIG. 2 (example 12) and a sintered body was manufactured by the conventional manufacturing method of FIG. 3 (comparative example 12). Table 9 is a table describing the preparation compositions, the compositions of the respective sintered bodies, the figures depicting the flowcharts of the manufacturing methods, and the Seebeck coefficients at room temperature. Referring to Table 9, the example 12 employing the manufacturing method of FIG. 2 contained a larger amount of Sb as compared to the comparative example 12 employing the manufacturing method of FIG. 3. It is considered that the sample exhibiting a larger absolute value of the Seebeck coefficient could consequently be acquired.

TABLE 9

| | | | | Seebeck |
|---|---|---|---|---|
| | | | | coefficient |
| | | | Manufac- | at Room |
| | Preparation | Sintered Body | turing | Temperature |
| | Composition | Composition | Method | (μV/K) |
| Example | Zr₃Ni₃Sb_{3.9}Sn_{0.1} | Zr_{3.11}Ni₃Sb_{3.85}Sn_{0.08} | FIG. 2 | 111 |
| 12 | | | | |
| Com- | Zr₃Ni₃Sb_{3.9}Sn_{0.1} | Zr_{2.89}Ni₃Sb_{3.74}Sn_{0.06} | FIG. 3 | 67.2 |
| parative | | | | |
| Example | | | | |
| 12 | | | | |

### Example 13 and Comparative Example 13

When a preparation composition was Zr₃Ni₃Sb_{3.7}Sn_{0.3}, a sintered body was manufactured by the manufacturing method according to this disclosure of FIG. 2 (example 13) and a sintered body was manufactured by the conventional manufacturing method of FIG. 3 (comparative example 13). Table 10 is a table describing the preparation compositions, the compositions of the respective sintered bodies, the figures depicting the flowcharts of the manufacturing methods, and the Seebeck coefficients at room temperature. Referring to Table 10, the example 13 employing the manufacturing method of FIG. 2 contained a larger amount of Sb as compared to the comparative example 13 employing the manufacturing method of FIG. 3. It is considered that the sample exhibiting a larger absolute value of the Seebeck coefficient could consequently be acquired.

TABLE 10

| | | | | Seebeck |
|---|---|---|---|---|
| | | | | co- |
| | | | | efficient |
| | | | | at Room |
| | | | Manu- | Temper- |
| | Preparation | Sintered Body | facturing | ature |
| | Composition | Composition | Method | (μV/K) |
| Example 13 | Zr₃Ni₃Sb_{3.7}Sn_{0.3} | Zr_{2.81}Ni₃Sb_{3.64}Sn_{0.26} | FIG. 2 | 73.1 |
| Comparative | Zr₃Ni₃Sb_{3.7}Sn_{0.3} | Zr_{2.86}Ni₃Sb_{3.43}Sn_{0.27} | FIG. 3 | 35.4 |
| Example 13 | | | | |

### Example 14 and Comparative Example 14

When a preparation composition was Zr₃Ni_{2.7}Pd_{0.3}Sb₄, a sintered body was manufactured by the manufacturing method according to this disclosure of FIG. 2 (example 14) and a sintered body was manufactured by the conventional manufacturing method of FIG. 3 (comparative example 14). Table 11 is a table describing the preparation compositions, the compositions of the respective sintered bodies, the figures depicting the flowcharts of the manufacturing methods, and the Seebeck coefficients at room temperature. Referring to Table 11, the example 14 employing the manufacturing method of FIG. 2 contained a larger amount of Sb as compared to the comparative example 14 employing the manufacturing method of FIG. 3. It is considered that the sample exhibiting a larger absolute value of the Seebeck coefficient could consequently be acquired. It is considered that using an element with a larger atomic number, i.e., a heavier element, such as Pd as an element substituted for Ni has an effect of decreasing the thermal conductivity κ and that the figure of merit can consequently be improved.

TABLE 11

| | | | | Seebeck |
|---|---|---|---|---|
| | | | | coefficient |
| | | | Manu- | at Room |
| | Preparation | Sintered Body | facturing | Temperature |
| | Composition | Composition | Method | (μV/K) |
| Example 14 | Zr₃Ni_{2.7}Pd_{0.3}Sb₄ | Zr_{3.29}Ni_{2.72}Pd_{0.28}Sb_{3.84} | FIG. 2 | 260 |
| Comparative | Zr₃Ni_{2.7}Pd_{0.3}Sb₄ | Zr_{3.12}Ni_{2.67}Pd_{0.33}Sb_{3.67} | FIG. 3 | 68.4 |
| Example 14 | | | | |

### Example 15 and Comparative Example 15

When a preparation composition was Zr₃Ni_{2.6}Pd_{0.3}Coₐ₁Sb₄, a sintered body was manufactured by the manufacturing method according to this disclosure of FIG. 2 (example 15) and a sintered body was manufactured by the conventional manufacturing method of FIG. 3 (comparative example 15). Table 12 is a table describing the preparation compositions, the compositions of the respective sintered bodies, the figures depicting the flowcharts of the manufacturing methods, and the Seebeck coefficients at room temperature. Referring to Table 12, the example 15 employing the manufacturing method of FIG. 2 contained a larger amount of Sb as compared to the comparative example 15 employing the manufacturing method of FIG. 3. It is considered that the sample exhibiting a larger absolute value of the Seebeck coefficient could consequently be acquired.

TABLE 12

| | | | | Seebeck |
|---|---|---|---|---|
| | | | | coefficient |
| | | | Manufac- | at Room |
| | Preparation | Sintered Body | turing | Temperature |
| | Composition | Composition | Method | (μV/K) |
| Example 15 | Zr₃Ni_{2.6}Pd_{0.3}Co_{0.1}Sb₄ | Zr_{2.86}Ni_{2.54}Pd_{0.36}Co_{0.1}Sb_{4.12} | FIG. 2 | 140 |
| Comparative | Zr₃Ni_{2.6}Pd_{0.3}Co_{0.1}Sb₄ | Zr_{3.1}Ni_{2.61}Pd_{0.32}Co_{0.7}Sb_{3.86} | FIG. 3 | 51 |
| Example 15 | | | | |

### Example 16 and Comparative Example 16

When a preparation composition was Zr₃Ni_{2.7}Pt_{0.3}Sb₄, a sintered body was manufactured by the manufacturing method according to this disclosure of FIG. 2 (example 16) and a sintered body was manufactured by the conventional manufacturing method of FIG. 3 (comparative example 16). Table 13 is a table describing the preparation compositions, the compositions of the respective sintered bodies, the figures depicting the flowcharts of the manufacturing methods, and the Seebeck coefficients at room temperature. Referring to Table 13, the example 16 employing the manufacturing method of FIG. 2 contained a larger amount of Sb as compared to the comparative example 16 employing the manufacturing method of FIG. 3. It is considered that the sample exhibiting a larger absolute value of the Seebeck coefficient could consequently be acquired. It is considered that using an element with a larger atomic number, i.e., a heavier element, such as Pt as an element substituted for Ni has an effect of decreasing the thermal conductivity κ and that the figure of merit can consequently be improved.

TABLE 13

| | | | | Seebeck |
|---|---|---|---|---|
| | | | | coefficient |
| | | | Manu- | at Room |
| | Preparation | Sintered Body | facturing | Temperature |
| | Composition | Composition | Method | (μV/K) |
| Example 16 | Zr₃Ni_{2.7}Pt_{0.3}Sb₄ | Zr_{2.83}Ni_{2.74}Co_{0.26}Sb_{3.99} | FIG. 2 | 317 |
| Comparative | Zr₃Ni_{2.7}Pt_{0.3}Sb₄ | Zr_{3.04}Ni_{2.72}Pt_{0.28}Sb_{3.87} | FIG. 3 | 59.1 |
| Example 16 | | | | |

### Example 17 and Comparative Example 17

When a preparation composition was Zr₃Ni_{2.6}Pt_{0.3}Co_{0.1}Sb₄, a sintered body was manufactured by the manufacturing method according to this disclosure of FIG. 2 (example 17) and a sintered body was manufactured by the conventional manufacturing method of FIG. 3 (comparative example 17). Table 14 is a table describing the preparation compositions, the compositions of the respective sintered bodies, the figures depicting the flowcharts of the manufacturing methods, and the Seebeck coefficients at room temperature. Referring to Table 14, the example 17 employing the manufacturing method of FIG. 2 contained a larger amount of Sb as compared to the comparative example 17 employing the manufacturing method of FIG. 3. It is considered that the sample exhibiting a larger absolute value of the Seebeck coefficient could consequently be acquired.

TABLE 14

| | | | | Seebeck |
|---|---|---|---|---|
| | | | | coefficient |
| | | | Manu- | at Room |
| | Preparation | Sintered Body | facturing | Temperature |
| | Compositon | Composition | Method | (μV/K) |
| Example 17 | Zr₃Ni_{2.6}Pt_{0.3}Co_{0.1}Sb₄ | Zr_{3.21}Ni_{2.55}Pt_{0.36}Co_{0.09}Sb_{3.86} | FIG. 2 | 144 |
| Comparative | Zr₃Ni_{2.6}Pt_{0.3}Co_{0.1}Sb₄ | Zr_{2.8}Ni_{2.66}Pt_{0.28}Co_{0.08}Sb_{3.77} | FIG. 3 | 43.9 |
| Example 17 | | | | |

### Example 18 and Comparative Example 18

When a preparation composition was Zr₃Ni_{2.9}Rh_{0.1}Sb₄, a sintered body was manufactured by the manufacturing method according to this disclosure of FIG. 2 (example 18) and a sintered body was manufactured by the conventional manufacturing method of FIG. 3 (comparative example 18). Table 15 is a table describing the preparation compositions, the compositions of the respective sintered bodies, the figures depicting the flowcharts of the manufacturing methods, and the Seebeck coefficients at room temperature. Referring to Table 15, the example 18 employing the manufacturing method of FIG. 2 contained a larger amount of Sb as compared to the comparative example 18 employing the manufacturing method of FIG. 3. It is considered that the sample exhibiting a larger absolute value of the Seebeck coefficient could consequently be acquired.

TABLE 15

| | | | | Seebeck |
|---|---|---|---|---|
| | | | | coefficient |
| | | | Manu- | at Room |
| | Preparation | Sintered Body | facturing | Temperature |
| | Composition | Composition | Method | (μV/K) |
| Example 18 | Zr₃Ni_{2.9}Rh_{0.1}Sb₄ | Zr_{3.06}Ni_{2.88}Rh_{0.12}Sb_{4.12} | FIG. 2 | 160 |
| Comparative | Zr₃Ni_{2.9}Rh_{0.1}Sb₄ | Zr_{3.13}Ni_{2.89}Rh_{0.11}Sb_{3.78} | FIG. 3 | 82.3 |
| Example 18 | | | | |

### Example 19 and Comparative Example 19

When a preparation composition was Zr₃Ni_{2.9}Ir_{0.1}Sb₄, a sintered body was manufactured by the manufacturing method according to this disclosure of FIG. 2 (example 19) and a sintered body was manufactured by the conventional manufacturing method of FIG. 3 (comparative example 19). Table 16 is a table describing the preparation compositions, the compositions of the respective sintered bodies, the figures depicting the flowcharts of the manufacturing methods, and the Seebeck coefficients at room temperature. Referring to Table 16, the example 19 employing the manufacturing method of FIG. 2 contained a larger amount of Sb as compared to the comparative example 19 employing the manufacturing method of FIG. 3. It is considered that the sample exhibiting a larger absolute value of the Seebeck coefficient could consequently be acquired.

TABLE 16

| | | | | Seebeck |
|---|---|---|---|---|
| | | | | coefficient at |
| | | | | Room |
| | Preparation | Sintered Body | Manufacturing | Temperature |
| | Composition | Composition | Method | (μV/K) |
| Example 19 | Zr₃Ni_{2.9}Ir_{0.1}Sb₄ | Zr_{3.05}Ni_{2.91}Ir_{0.09}Sb_{4.03} | FIG. 2 | 204 |
| Comparative | Zr₃Ni_{2.9}Ir_{0.1}Sb₄ | Zr_{3.09}Ni_{2.87}Ir_{0.13}Sb_{3.84} | FIG. 3 | 96.5 |
| Example 19 | | | | |

### Example 20 and Comparative Example 20

When a preparation composition was Zr_{2.9}Y_{0.1}Ni₃Sb₄, a sintered body was manufactured by the manufacturing method according to this disclosure of FIG. 2 (example 20) and a sintered body was manufactured by the conventional manufacturing method of FIG. 3 (comparative example 20). Table 17 is a table describing the preparation compositions, the compositions of the respective sintered bodies, the figures depicting the flowcharts of the manufacturing methods, and the Seebeck coefficients at room temperature. Referring to Table 17, the example 20 employing the manufacturing method of FIG. 2 contained a larger amount of Sb as compared to the comparative example 20 employing the manufacturing method of FIG. 3. It is considered that the sample exhibiting a larger absolute value of the Seebeck coefficient could consequently be acquired.

TABLE 17

| | | | | Seebeck |
|---|---|---|---|---|
| | | | | coefficient |
| | | | | at Room |
| | Preparation | Sintered Body | Manufacturing | Temperature |
| | Composition | Composition | Method | (μV/K) |
| Example 20 | Zr_{2.9}Y_{0.1}Ni₃Sb₄ | Zr_{2.79}Y_{0.12}Ni₃Sb_{3.92} | FIG. 2 | 87.7 |
| Comparative | Zr_{2.9}Y_{0.1}Ni₃Sb₄ | Zr_{2.96}Y_{0.09}Ni₃Sb_{3.76} | FIG. 3 | 45.4 |
| Example 20 | | | | |

### Example 21 and Comparative Example 21

When a preparation composition was Zr_{2.9}La_{0.1}Ni₃Sb₄, a sintered body was manufactured by the manufacturing method according to this disclosure of FIG. 2 (example 21) and a sintered body was manufactured by the conventional manufacturing method of FIG. 3 (comparative example 21). Table 18 is a table describing the preparation compositions, the compositions of the respective sintered bodies, the figures depicting the flowcharts of the manufacturing methods, and the Seebeck coefficients at room temperature. Referring to Table 18, the example 21 employing the manufacturing method of FIG. 2 contained a larger amount of Sb as compared to the comparative example 21 employing the manufacturing method of FIG. 3. It is considered that the sample exhibiting a larger absolute value of the Seebeck coefficient could consequently be acquired.

TABLE 18

| | | | | Seebeck |
|---|---|---|---|---|
| | | | | coeffi- |
| | | | | cient |
| | | | | at Room |
| | | | Manu- | Temp- |
| | Preparation | Sintered Body | facturing | erature |
| | Composition | Composition | Method | (μV/K) |
| Example 21 | Zr_{2.9}La_{0.1}Ni₃Sb₄ | Zr_{2.92}La_{0.14}Ni₃Sb_{4.02} | FIG. 2 | 114 |
| Comparative | Zr_{2.9}La_{0.1}Ni₃Sb₄ | Zr_{2.84}La_{0.13}Ni₃Sb_{3.79} | FIG. 3 | 52.9 |
| Example 21 | | | | |

### Example 22 and Comparative Example 22

When a preparation composition was Zr₃Ni₃Sb_{3.9}Ge_{0.1}, a sintered body was manufactured by the manufacturing method according to this disclosure of FIG. 2 (example 22) and a sintered body was manufactured by the conventional manufacturing method of FIG. 3 (comparative example 22). Table 19 is a table describing the preparation compositions, the compositions of the respective sintered bodies, the figures depicting the flowcharts of the manufacturing methods, and the Seebeck coefficients at room temperature. Referring to Table 19, the example 22 employing the manufacturing method of FIG. 2 contained a larger amount of Sb as compared to the comparative example 22 employing the manufacturing method of FIG. 3. It is considered that the sample exhibiting a larger absolute value of the Seebeck coefficient could consequently be acquired.

TABLE 19

| | | | | Seebeck |
|---|---|---|---|---|
| | | | | coeffi- |
| | | | | cient |
| | | | | at |
| | | | | Room |
| | | | Manu- | Temp- |
| | Preparation | Sintered Body | facturing | erature |
| | Composition | Composition | Method | (μV/K) |
| Example 22 | Zr₃Ni₃Sb_{3.9}Ge_{0.1} | Zr_{2.91}Ni₃Sb_{3.91}Ge_{0.08} | FIG. 2 | 253 |
| Comparative | Zr₃Ni₃Sb_{3.9}Ge_{0.1} | Zr_{3.11}Ni₃Sb_{3.67}Ge_{0.11} | FIG. 3 | 69 |
| Example 22 | | | | |

### Example 23 and Comparative Example 23

When a preparation composition was Zr_{2.9}Nb_{0.1}Ni₃Sb₄, a sintered body was manufactured by the manufacturing method according to this disclosure of FIG. 2 (example 23) and a sintered body was manufactured by the conventional manufacturing method of FIG. 3 (comparative example 23). Table 20 is a table describing the preparation compositions, the compositions of the respective sintered bodies, the figures depicting the flowcharts of the manufacturing methods, and the Seebeck coefficients at room temperature. Referring to Table 20, the example 23 employing the manufacturing method of FIG. 2 contained a larger amount of Sb as compared to the comparative example 23 employing the manufacturing method of FIG. 3. It is considered that the sample exhibiting a larger absolute value of the Seebeck coefficient could consequently be acquired. If Nb is used for a dopant substituted for Zr, an electron-doped n-type semiconductor is provided and the Seebeck coefficient S takes a negative value (S<0).

TABLE 20

| | | | | Seebeck |
|---|---|---|---|---|
| | | | | coefficient at |
| | | | | Room |
| | Preparation | Sintered Body | Manufacturing | Temperature |
| | Composition | Composition | Method | (μV/K) |
| Example 23 | Zr_{2.9}Nb_{0.1}Ni₃Sb₄ | Zr_{2.76}Nb_{0.07}Ni₃Sb_{4.11} | FIG. 2 | −246 |
| Comparative | Zr_{2.9}Nb_{0.1}Ni₃Sb₄ | Zr_{2.85}Nb_{0.08}Ni₃Sb_{3.79} | FIG. 3 | 32.5 |
| Example 23 | | | | |

### Example 24 and Comparative Example 24

When a preparation composition was Zr_{2.9}Ta_{0.1}Ni₃Sb₄, a sintered body was manufactured by the manufacturing method according to this disclosure of FIG. 2 (example 24) and a sintered body was manufactured by the conventional manufacturing method of FIG. 3 (comparative example 24). Table 21 is a table describing the preparation compositions, the compositions of the respective sintered bodies, the figures depicting the flowcharts of the manufacturing methods, and the Seebeck coefficients at room temperature. Referring to Table 21, the example 24 employing the manufacturing method of FIG. 2 contained a larger amount of Sb as compared to the comparative example 24 employing the manufacturing method of FIG. 3. It is considered that the sample exhibiting a larger absolute value of the Seebeck coefficient could consequently be acquired. If Ta is used for a dopant substituted for Zr, an electron-doped n-type semiconductor is provided and the Seebeck coefficient S takes a negative value (S<0).

TABLE 21

| | | | | Seebeck |
|---|---|---|---|---|
| | | | | coefficient at |
| | | | | Room |
| | Preparation | Sintered Body | Manufacturing | Temperature |
| | Composition | Composition | Method | (μV/K) |
| Example 24 | Zr_{2.9}Ta_{0.1}Ni₃Sb₄ | Zr_{2.92}Ta_{0.12}Ni₃Sb_{3.98} | FIG. 2 | −141 |
| Comparative | Zr_{2.9}Ta_{0.1}Ni₃Sb₄ | Zr_{2.82}Ta_{0.11}Ni₃Sb_{3.67} | FIG. 3 | −41.2 |
| Example 24 | | | | |

Tables 2-21 show the Seebeck coefficient of the examples and comparative examples of the thermoelectric conversion material expressed in the chemical formula X₃Ni₃Sb₄ (X is Zr or Hf), when X is partially replaced with Y, La, Nb, Ta; Ni is partially replaced with Co, Cu, Rh, Pd, Ir, Pt; Sb is partially replaced with Ge, Sn. It is noted that it is hardly to define the actual composition of the example with three-digits accuracy by using the energy dispersive X-ray spectroscopy (EDX). Referring to Tables 2-21 in whole, each example employing the manufacturing method of FIG. 2 contained a larger amount of Sb as compared to the comparative example employing the manufacturing method of FIG. 3, the comparative example having the same number of the example. It is considered that the sample exhibiting a larger absolute value of the Seebeck coefficient could consequently be acquired.

As described above, the thermoelectric conversion material created by the manufacturing method of this disclosure reduced a loss of Sb as compared to conventional cases and had excellent thermoelectric conversion performance.

The method of manufacturing a thermoelectric conversion material according to this disclosure can be used for forming a thermoelectric conversion material performing thermoelectric power generation or thermoelectric cooling.

### EXPLANATIONS OF LETTERS OR NUMERALS

11 atom position (black) of X=Zr, Hf, Y, La, Nb, Ta in a X₃T₃Z₄ crystal
12 atom position (grey) of T=Ni, Co, Cu, Rh, Pd, Ir, Pt in the X₃T₃Z₄ crystal
13 atom position (white) of Z=Sb, Ge, Sn in the X₃T₃Z₄ crystal

1. A method of manufacturing a thermoelectric conversion material expressed by a chemical formula X₃T₃Z₄ (X is composed of one or more elements selected from Zr, Hf, Y, La, Nb, and Ta, while including at least Zr or Hf; T is composed of one or more elements selected from Ni, Co, Cu, Rh, Pd, Ir, and Pt, while including at least Ni; Z is composed of one or more elements selected from Sb, Ge, and Sn, while including at least Sb), the method comprising:
preparing materials containing elements, which are one or more elements selected from Zr, Hf, Y, La, Nb, and Ta, while including at least Zr or Hf, one or more elements selected from Ni, Co, Cu, Rh, Pd, Ir, and Pt, while including at least Ni, and one or more elements selected from Sb, Ge, and Sn, while including at least Sb;
forming an alloy A by melting the materials containing desired elements selected from Zr, Hf, Y, La, Nb, Ta, Ni, Co, Cu, Rh, Pd, Ir, Pt, Ge, and Sn; and
forming an alloy B by melting the alloy A and the material containing Sb.

2. The method of manufacturing a thermoelectric conversion material according to claim 1, wherein the step of forming the alloy A is performed by any one of an arc melting method, an electromagnetic induction heating method, and a heating method using a resistance heating element.

3. The method of manufacturing a thermoelectric conversion material according to claim 1, wherein in the step of forming the alloy A, the alloy A is formed by melting the materials containing the elements except the material containing Sb at 2000° C. or higher.

4. The method of manufacturing a thermoelectric conversion material according to claim 1, wherein in the step of forming the alloy B, the alloy B is formed by melting the alloy A and the material containing Sb at 1500° C. or lower.

5. The method of manufacturing a thermoelectric conversion material according to claim 1, further comprising a step of forming a sintered body having a density higher than the alloy B by using the alloy B after the step of forming the alloy B.

6. The method of manufacturing a thermoelectric conversion material according to claim 5, wherein the step of forming a sintered body having a density higher than the alloy B by using the alloy B is performed by either a hot press method or a spark plasma sintering method (SPS method).

7. The method of manufacturing a thermoelectric conversion material according to claim 1, wherein X is composed of one or more elements selected from Zr and Hf; T is composed of one or more elements selected from Ni, Co, Cu, Pd, and Pt, while including at least Ni; Z is composed of one or more elements selected from Sb and Sn, while including at least Sb.
